(19) United States
(12) Patent Application Publication
(10) Pub. No.: US 2011/0220405 A1
(43) Pub. Date: Sep. 15, 2011

(54) METHOD FOR MANUFACTURING MULTILAYER PRINTED WIRING BOARD AND MULTILAYER PRINTED WIRING BOARD

(75) Inventor: Kazuhisa TSUNOI, Kawasaki (JP)

(73) Assignee: FUJITSU LIMITED, KAWASAKI (JP)

(21) Appl. No.: 12/961,003

(22) Filed: Dec. 6, 2010

(30) Foreign Application Priority Data
Mar. 10, 2010 (JP) 2010-52600

(51) Int. Cl. H05K 1/11; H05K 3/36

(52) U.S. Cl. 174/264; 29/830

(57) ABSTRACT

A method for manufacturing a multilayer printed wiring board, the method includes forming a group of first through holes in a first insulating substrate; forming a group of second through holes in a second insulating substrate that has the same shape and the same size as a shape and a size, respectively, of the first insulating substrate, the second through holes having the same shape and the same size as a shape and a size, respectively, of the first through holes and being formed at the same positions as positions at which the first through holes are formed. At least one of the first through holes is filled with a first conductive member and at least one of the second through holes is filled with a second conductive member. And stacking the first insulating substrate and the second insulating substrate together.

### CROSS-REFERENCE TO RELATED APPLICATIONS

This application is based upon and claims the benefit of priority from the prior Japanese Patent Application No. 2010-52600 filed on Mar. 10, 2010, the entire contents of which are incorporated herein by reference.

### FIELD

The present embodiment relates to a method for manufacturing a multilayer printed wiring board and a multilayer printed wiring board.

### BACKGROUND

Japanese Unexamined Patent Application Publications Nos. 9-162517, 10-284837, 62-98694, and 2006-120769, which are examples of the related art, disclose a technique of processing holes formed in substrates.

### SUMMARY

According to an aspect of an embodiment, a method for manufacturing a multilayer printed wiring board, the method includes forming a group of first through holes in a first insulating substrate, forming a group of second through holes in a second insulating substrate that has the same shape and the same size as a shape and a size, respectively, of the first insulating substrate, the second through holes having the same shape and the same size as a shape and a size, respectively, of the first through holes and being formed at the same positions as positions at which the first through holes are formed, filling at least one of the first through holes with a first conductive member, filling at least one of the second through holes with a second conductive member, and stacking the first insulating substrate and the second insulating substrate together.

The object and advantages of the various embodiments will be realized and attained by means of the elements and combinations particularly pointed out in the claims. It is to be understood that both the foregoing general description and the following detailed description are exemplary and explanatory and are not restrictive of the various embodiments, as claimed.

Additional aspects and/or advantages will be set forth in part in the description which follows and, in part, will be apparent from the description, or may be learned by practice of the various embodiments.

### BRIEF DESCRIPTION OF THE DRAWINGS

FIG. 1 is a flowchart of a method for manufacturing a multilayer printed wiring board according to the present embodiment;

FIGS. 2A to 2F are schematic diagrams illustrating the method for manufacturing the multilayer printed wiring board;

FIGS. 3A to 3C are diagrams illustrating a mechanism for filling holes with insulating members;

FIG. 4A is a diagram illustrating a filling mechanism for filling the holes with the insulating members;

FIG. 4B is a diagram illustrating a discharging mechanism for discharging the insulating members from the holes;

FIG. 5A is a diagram illustrating a filling mechanism for filling the holes with conductive members;

FIG. 5B is a diagram illustrating a modification of the filling mechanism for filling the holes with the conductive members;

FIGS. 6A and 6B are diagrams illustrating the manner in which a wiring pattern is formed;

FIG. 7 is a diagram illustrating a modification of a stacking method; and

FIGS. 8A to 8C are diagrams illustrating modifications of the conductive members.

### DESCRIPTION OF EMBODIMENTS

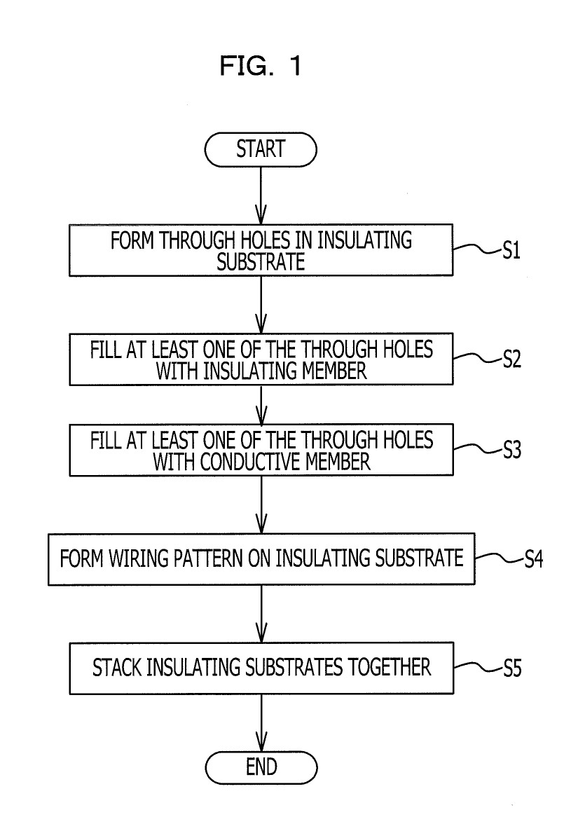

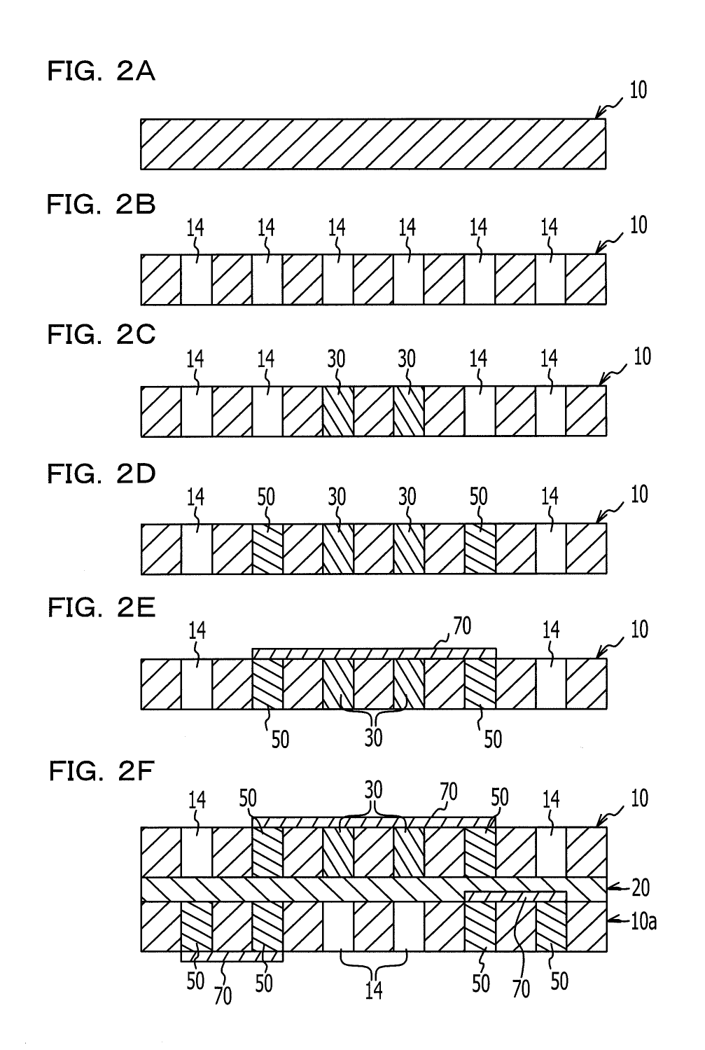

A method for manufacturing a multilayer printed wiring board according to the present embodiment will now be described. FIG. 1 is a flowchart of the method for manufacturing the multilayer printed wiring board according to the present embodiment. FIGS. 2A to 2F are schematic diagrams illustrating the method for manufacturing the multilayer printed wiring board. As illustrated in FIGS. 1, 2A, and 2B, in the manufacturing method according to the present embodiment, a plurality of through holes 14 are formed in an insulating substrate 10 (S1). The insulating substrate 10 is a rigid synthetic resin substrate made of, for example, polyimide resin or glass epoxy resin. The through holes 14 are formed by, for example, a punching tool, a mechanical drill, or a laser. The through holes 14 are formed such that constant intervals are provided therebetween. For example, the intervals between the through holes 14 are constant in a first direction along a plane of the insulating substrate 10, and are also constant in a second direction along the plane of the insulating substrate 10.

As illustrated in FIG. 2C, in the next operation of the manufacturing method according to the present embodiment, at least one of the through holes 14 is filled with an insulating member 30 (S2). In the example illustrated in FIG. 2C, two through holes 14 are filled with insulating members 30. The process of filling the through holes 14 with the insulating members 30 will be described in detail below. The insulating members 30 may be made of, for example, epoxy-based synthetic resin or a resin in which alumina having a high heat dissipation effect is mixed.

As illustrated in FIG. 2D, in the next operation of the manufacturing method according to the present embodiment, at least one of the through holes 14 is filled with a conductive member 50 (S3). In the example illustrated in FIG. 2D, two through holes 14 are filled with conductive members 50. The conductive members 50 are made of metal, such as copper, aluminum, nickel, gold, silver, palladium, or an alloy thereof. The process of filling the through holes 14 with the conductive members 50 will be described in detail below.

As illustrated in FIG. 2E, in the next operation of the manufacturing method according to the present embodiment, a wiring pattern 70 for electrically connecting the conductive members 50 to each other is formed on the insulating substrate 10 (S4). The wiring pattern 70 is formed by, for example, a method using a dispenser, a transferring method, a plating method, or a screen printing method. The wiring pattern 70 is made of, for example, a copper foil or a copper paste. In the process of forming the wiring pattern 70, the wiring pattern 70 is formed so as to extend along surfaces of the conductive members 50. Thus, the through holes 14 at positions where the wiring pattern 70 is to be formed are filled with the conductive members 50 before the wiring pattern 70 is formed.

In the manufacturing method according to the present embodiment, another insulating substrate 10a that is different from the insulating substrate 10 is subjected to S1 to S4. Then, the insulating substrates 10 and 10a are stacked together (S5). The insulating substrates 10 and 10a are bonded to each other by an adhesive member 20. The adhesive member 20 is insulative. The adhesive member 20 is, for example, sheet shaped, and is made of a material such as thermo-setting resin or pre-impregnation material. The adhesive member 20 may be formed of an anisotropic resin, as described below. Although a multilayer printed wiring board including two layers is illustrated in FIG. 2F, the number of layers may be more than two.

The insulating substrate 10 and the insulating substrate 10a can have the same shape before they are processed. According to an aspect of an embodiment, the substrate shapes can be different. The shape, size, and positions of the through holes 14 formed in the insulating substrate 10a are the same as those of the through holes 14 formed in the insulating substrate 10. In other words, for example, the insulating substrates 10 and 10a immediately after the through holes 14 are formed therein have the same shape with the same hole 14 shapes, sizes and positions. The phrase ‘same’ also refers to similar. According to an aspect of an embodiment, any combination of through hole 14 shapes, sizes or positions of two or more substrates may be same or have a common structure.

As described above, the multilayer printed wiring board according to the present embodiment is manufactured using insulating substrates having a common structure. In contrast, when a plurality of insulating substrates that are individually processed in accordance with different design conditions are used, there is a risk that the yield will be reduced owing to the complex design conditions. In the multilayer printed wiring board according to the present embodiment, the yield is increased since the insulating substrates having a common structure are used.

When the through holes 14 are formed in each of the insulating substrates 10 and 10a having the same shape, the insulating substrates 10 and 10a may be placed on top of each other and the through holes 14 may be formed simultaneously in both of the insulating substrates 10 and 10a. In this case, the through holes 14 may be formed by, for example, a punching tool, a mechanical drill, or a laser.

As illustrated in FIG. 2F, one or more of the through holes 14 and/or other type of through hole can remain/be provided as a hollow hole. When at least one of the through holes 14 in the insulating substrate 10 remains as the hollow hole, warping of the multilayer printed wiring board is absorbed by the through hole 14 that remains as the hollow hole. Therefore, warping of the multilayer printed wiring board is suppressed.

A signal propagation delay time at the wiring pattern formed near the through hole 14 that remains as the hollow hole is reduced. In general, a signal propagation delay time τ may be calculated as follows:

τ=1/v=√∈/C

In this equation, v is the propagation velocity, E is the relative dielectric constant, and C is the velocity of light. The signal propagation delay time τ is reduced as the relative dielectric constant ∈ is reduced. The dielectric constant of air is 1, and the dielectric constant of a common glass epoxy resin is about 4.5. The through hole 14 that remains as the hollow hole in the insulating substrate 10 is filled with air. Therefore, the dielectric constant of the entire body of the multilayer printed wiring board is reduced. As a result, the signal propagation delay time is reduced.

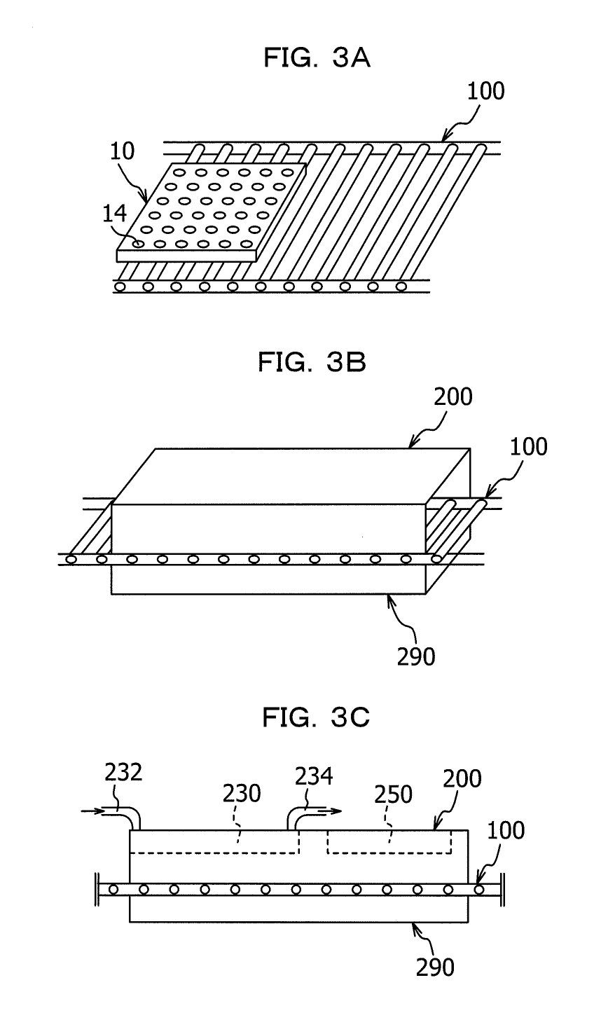

A mechanism for filling the through holes 14 with the insulating members 30 will now be described. FIGS. 3A to 3C are diagrams illustrating a filling-and-discharging mechanism 200 for filling the through holes 14 with the insulating members 30. As illustrated in FIG. 3A, the insulating substrate 10 in which the through holes 14 are formed is conveyed by a conveying mechanism 100. As illustrated in FIG. 3B, the filling-and-discharging mechanism 200 and a collecting mechanism 290 are disposed along a conveying path of the conveying mechanism 100 at an upper side and a lower side, respectively, of the conveying mechanism 100. As illustrated in FIG. 3C, the filling-and-discharging mechanism 200 includes a filling mechanism 230 provided at an upstream position in a conveying direction and a discharging mechanism 250 provided at a downstream position in the conveying direction. The conveying mechanism 100 includes two rails that are parallel to each other and rollers that are rotatably supported between the two rails. However, the structure of the conveying mechanism 100 is not limited to this.

A delivery tube 232 and a suction tube 234 are connected to the filling mechanism 230. The delivery tube 232 is used to supply the insulating members 30 to the filling mechanism 230 by using compressed air. The suction tube 234 sucks out the air in the filling mechanism 230 to collect the insulating members 30 that remain in the filling mechanism 230. A pump (not illustrated) is connected to each of the delivery tube 232 and the suction tube 234.

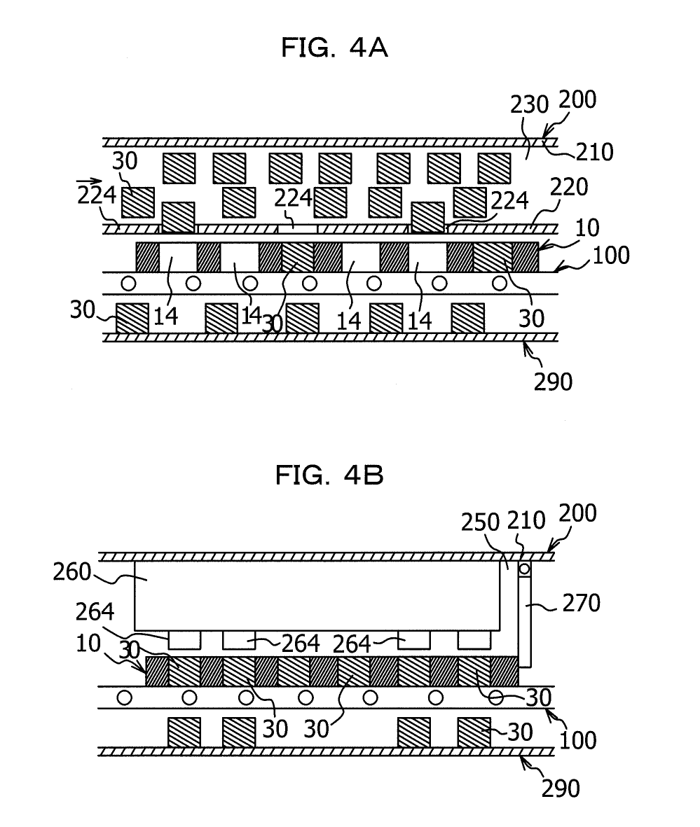

FIG. 4A is a diagram illustrating the filling mechanism 230 that fills the through holes 14 with the insulating members 30. The filling mechanism 230 includes an upper wall 210 and a lower wall 220. The insulating members 30 are supplied to the filling mechanism 230. A plurality of discharge holes 224 are formed in the lower wall 220. The insulating members 30 are ejected from the discharge holes 224 toward the insulating substrate 10 by the compressed air injected into the filling mechanism 230. Some of the insulating members 30 ejected from the discharge holes 224 are placed in the through holes 14. The insulating members 30 that have not been placed in the through holes 14 fall from the conveying mechanism 100 and are collected by the collecting mechanism 290. Thus, for example, according to an aspect of an embodiment, all of the through holes 14 formed in the insulating substrate 10 are filled with the insulating members 30. Then, the insulating substrate 10 leaves the filling mechanism 230 and moves to a position below the discharging mechanism 250.

FIG. 4B is a diagram illustrating the discharging mechanism 250 that discharges the insulating members 30. A pressing jig 260 is connected to the upper wall 210 such that the pressing jig 260 is vertically movable. The pressing jig 260 is vertically moved by, for example, a hydraulic cylinder or a pneumatic cylinder. The pressing jig 260 includes a plurality of projecting portions 264 that project toward the insulating substrate 10. A stopper 270 for retaining the insulating substrate 10 conveyed by the conveying mechanism 100 at a certain position is connected to the upper wall 210. The stopper 270 is connected to the upper wall 210 such that the stopper 270 is swingable between a position at which the stopper 270 comes into contact with the insulating substrate 10 and a position at which the stopper 270 is separated from the insulating substrate 10.

The insulating substrate 10 is stopped by the stopper 270. The pressing jig 260 is moved downward toward the insulating substrate 10, so that some of the insulating members 30 are pushed out of the through holes 14 by the projecting portions 264. The positions of the projecting portions 264 correspond to the positions at which the through holes 14 are formed in the insulating substrate 10. The positions of the projecting portions 264 are set in advance so that the insulating members 30 at desired positions are discharged. The insulating members 30 that are pushed out of the through holes 14 are collected by the collecting mechanism 290 disposed below the conveying mechanism 100. After the insulating members 30 are pushed out, the pressing jig 260 moves upward away from the insulating substrate 10. Accordingly, the stopper 270 also moves away from the insulating substrate 10. Thus, the insulating substrate 10 is conveyed by the conveying mechanism 100 such that the desired through holes 14 are filled with the insulating members 30.

Here, a plurality of pressing jigs 260 in which the projecting portions 264 are formed at different positions may be prepared. In such a case, the process of pushing out the insulating members 30 may be performed by selectively using the pressing jigs 260 in accordance with the insulating substrate.

The desired through holes 14 are filled with the insulating members 30 by the above-described method. More specifically, for example, all of the through holes 14 are filled with the insulating members 30 in a batch process, and then unnecessary (e.g., not desired) insulating members 30 are discharged in another batch process. Therefore, compared to the case in which preselected through holes 14 in the through holes 14 are individually filled with the insulating members 30, the process time is reduced and the yield is increased.

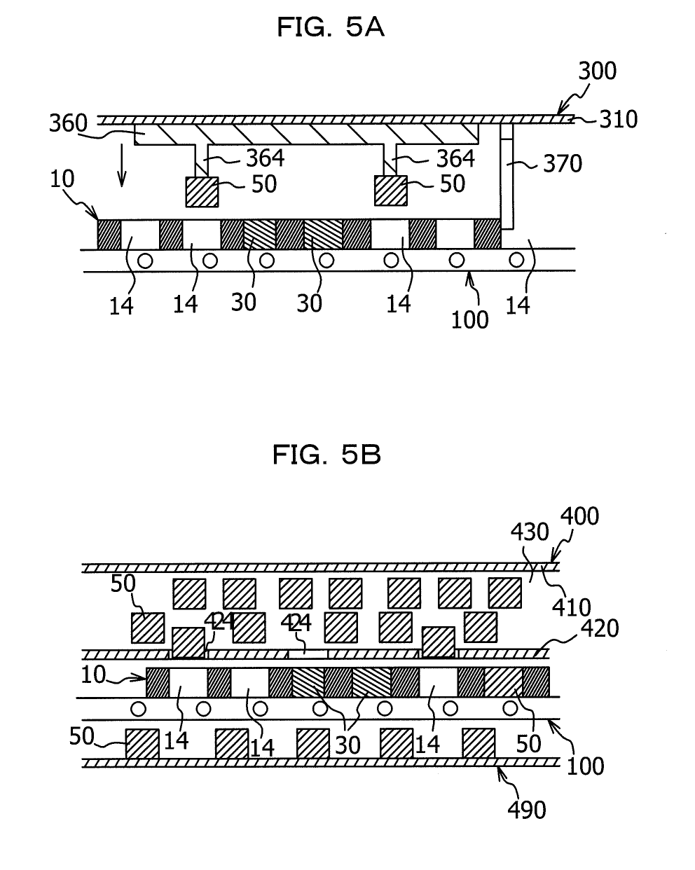

A filling mechanism for filling the through holes 14 with the conductive members 50 will now be described. FIG. 5A is a diagram illustrating a filling mechanism 300 that fills the through holes 14 with the conductive members 50. As illustrated in FIG. 5A, the filling mechanism 300 is disposed along the conveying path of the conveying mechanism 100. A pressing jig 360 is connected to an upper plate 310 of the filling mechanism 300 such that the pressing jig 360 is vertically movable. The pressing jig 360 is vertically moved by, for example, a hydraulic cylinder or a pneumatic cylinder. The pressing jig 360 is provided with projecting portions 364 at certain positions. The projecting portions 364 project toward the insulating substrate 10. The conductive members 50 are fixed to the projecting portions 364 at the ends thereof. The positions of the projecting portions 364 are set in advance so that the through holes 14 at the desired positions are filled with the conductive members 50. A stopper 370 is connected to the upper plate 310 in a swingable manner. The stopper 370 is swingable between a position at which the stopper 370 comes into contact with the insulating substrate 10 and a position at which the stopper 370 is separated from the insulating substrate 10.

The insulating substrate 10 is stopped by the stopper 370, and the pressing jig 360 is moved downward toward the insulating substrate 10, so that the desired through holes 14 are filled with the conductive members 50 attached to the projecting portions 364. Thus, the desired through holes 14 are filled with the conductive members 50. After the through holes 14 are filled with the conductive members 50, the pressing jig 360 moves upward away from the insulating substrate 10. Accordingly, the stopper 370 also moves away from the insulating substrate 10. Thus, the insulating substrate 10 is conveyed by the conveying mechanism 100 such that the desired through holes 14 are filled with the conductive members 50 and the insulating members 30.

Here, a plurality of pressing jigs 360 in which the projecting portions 364 are formed at different positions may be prepared. In such a case, the process of filling the through holes 14 with the conductive members 50 may be performed by selectively using the prepared pressing jigs 360 in accordance with the insulating substrate (corresponding to the respective insulating substrates).

A modification of the filling mechanism for filling the through holes 14 with the conductive members 50 will now be described. FIG. 5B is a diagram illustrating a modification of the filling mechanism that fills the through holes 14 with the conductive members 50. A mechanism 400 includes a filling mechanism 430. The mechanism 400 is disposed at an upper side of the conveying mechanism 100. The filling mechanism 430 includes an upper plate 410 and a lower plate 420. The conductive members 50 are supplied to the filling mechanism 430. Similar to the above-described filling mechanism 230, a delivery tube and a suction tube are connected to the filling mechanism 430. The delivery tube is used to supply the conductive members 50 to the filling mechanism 430 by using compressed air. The suction tube sucks out the air in the filling mechanism 430 to collect the conductive members 50 that remain in the filling mechanism 430.

A plurality of discharge holes 424 are formed in the lower plate 420. The conductive members 50 are discharged from the discharge holes 424 toward the insulating substrate 10. The through holes 14 that are not filled with the insulating members 30 are filled with the conductive members 50. The filling mechanism 400 is advantageous for use in the process of filling all of the through holes 14 that are not filled with the insulating members 30 with the conductive members 50. The conductive members 50 that have not been placed in the through holes 14 are collected by a collecting mechanism 490 disposed at a lower side of the conveying mechanism 100.

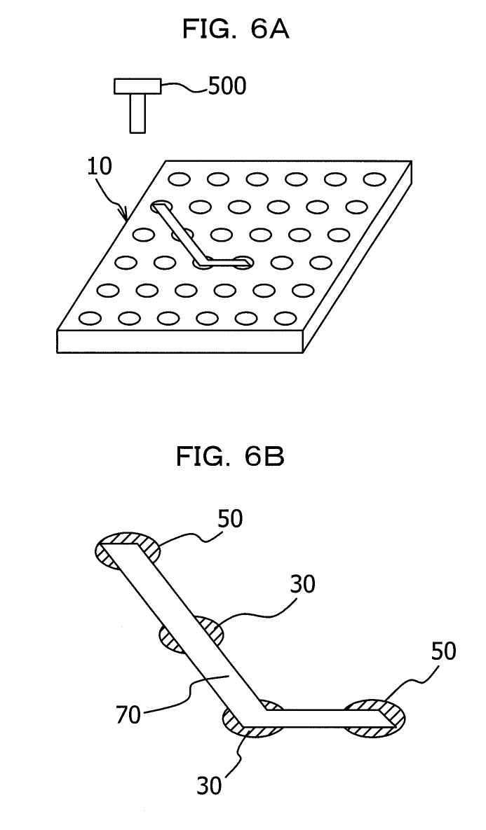

A process of forming the wiring pattern 70 will now be described. FIGS. 6A and 6B are diagrams illustrating the manner in which the wiring pattern 70 is formed. As illustrated in FIGS. 6A and 6B, the wiring pattern 70 is formed so as to connect the conductive members 50 with which the through holes 14 are filled. The wiring pattern 70 is formed on a surface of the insulating substrate 10 using a dispenser 500. The wiring pattern 70 is formed so as to pass (e.g., pass over) the insulating members 30 with which the through holes 14 are filled. Accordingly, the freedom of the shape and position of the wiring pattern 70 may be prevented from being limited by the through holes 14.

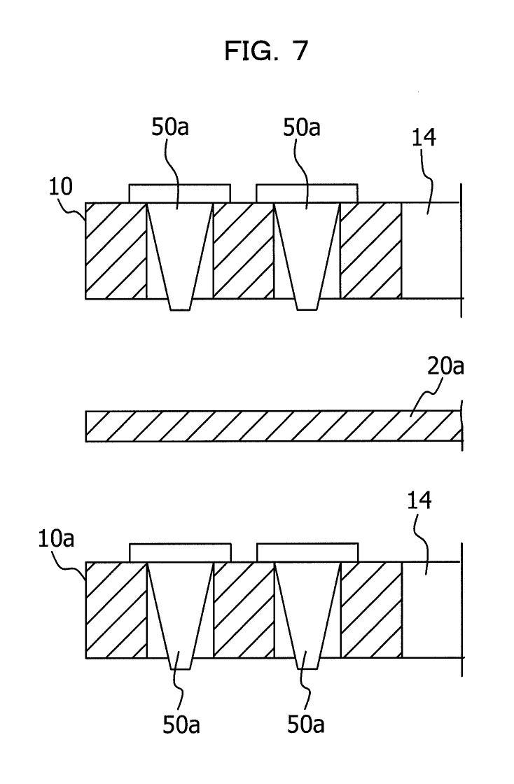

A modification of the stacking method will now be described. FIG. 7 is a diagram illustrating a modification of the stacking method. The conductive members with which the through holes 14 in the insulating substrate 10 are filled may be conductive members 50a illustrated in FIG. 7. The length of the conductive members 50a is greater than the thickness of the insulating substrate 10. The insulating substrate 10 and the insulating substrate 10a are bonded to each other by an adhesive member 20a. When the insulating substrates 10 and 10a are stacked together, tip ends of the conductive members 50a placed in the through holes 14 in the insulating substrate 10 come into contact with base ends of the conductive members 50a placed in the through holes 14 in the insulating substrate 10a. Accordingly, an interlayer connection between the insulating substrates 10 and 10a is provided.

The conductive members may be structured such that the conductive members do not project from the insulating substrate 10 as illustrated in FIG. 7. When the tip ends of the conductive members placed in the through holes 14 in the insulating substrate 10 do not project from the insulating substrate 10, the insulating substrates 10 and 10a may be stacked together using anisotropic adhesive. In this case, the tip ends of the conductive members in the insulating substrate 10 are electrically connected to the base ends of the conductive members in the insulating substrate 10a through metal powder contained in the anisotropic adhesive. Thus, the above-described conductive members may be used.

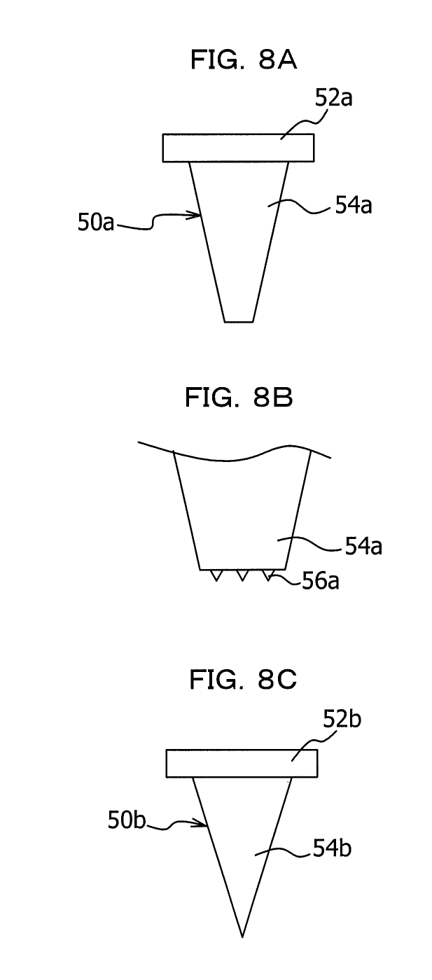

FIGS. 8A to 8C are diagrams illustrating modifications of the conductive members. A conductive member 50a illustrated in FIG. 8A includes a flange portion 52a and a body portion 54a. The body portion 54a has a substantially truncated conical shape. The diameter of the flange portion 52a is greater than the diameter of the through holes 14 in the insulating substrate 10. The length of the body portion 54a is greater than the thickness of the insulating substrate 10. FIG. 8B illustrates an enlarged view of a tip end of the body portion 54a. Projections 56a are formed on the body portion 54a. Three projections 56a, for example, are provided. Since the projections 56a are provided, an electrical connection between each conductive member in the upper insulating substrate and the corresponding conductive member in the lower insulating substrate is ensured.

Another conductive member 50b illustrated in FIG. 8C includes a flange portion 52b and a body portion 54b. The body portion 54b has a substantially conical shape. The length of the body portion 54b is greater than the thickness of the insulating substrate 10. Also when the conductive members are formed in this shape, an electrical connection between each conductive member in the upper insulating substrate and the corresponding conductive member in the lower insulating substrate is ensured.

Although a preferred embodiment of the present invention is described above, the present invention is not limited to any specific embodiment, and various modifications and alterations are possible within the scope of the present invention as described in the claims.

In the above-described embodiment, the through holes 14 are filled with the conductive members 50 that are prepared in advance. However, the filling method is not limited to this. For example, the through holes 14 may be filled with copper paste (conductive member) using a dispenser or the like, and then a wiring pattern may be formed on the through holes 14 that are filled with the copper paste.

According to an aspect of the embodiments of the invention, any combinations of one or more of the described substrates, members, features, functions, operations, and/or benefits can be provided. A combination can be one or a plurality.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A method for manufacturing a multilayer printed wiring board, the method comprising:
forming a group of first through holes in a first insulating substrate;
forming a group of second through holes in a second insulating substrate that has same shape and same size as a shape and a size, respectively, of the first insulating substrate, the second through holes having same shape and same size as a shape and a size, respectively, of the first through holes and being formed at same positions as positions at which the first through holes are formed;
filling at least one of the first through holes with a first conductive member;
filling at least one of the second through holes with a second conductive member; and
stacking the first insulating substrate and the second insulating substrate together.

2. The method according to claim 1, the method further comprising:
filling at least one of the first through holes with a first insulating member; and
forming a wiring pattern on the first insulating substrate such that the wiring pattern passes the insulating member.

3. The method according to claim 1, wherein at least one of the first through holes is hollow.

4. The method according to claim 1, wherein upon the filling of the first through holes, the first conductive member projects from and/or does not project from the first insulating substrate.

5. The method according to claim 4, wherein when the first conductive member projects from the first insulating substrate, the first conductive member has a substantially truncated conical shape with one or more projections formed on a tip of the truncated cone and/or a substantially conical shape.

6. A multilayer printed wiring board, comprising:
a first insulating substrate provided with a group of first through holes;
a second insulating substrate having same shape and same size as a shape and a size, respectively, of the first insulating substrate and stacked on the first insulating substrate, the second insulating substrate being provided with a group of second through holes having same shape and same size as a shape and a size, respectively, of the first through holes and provided at same positions as positions at which the first through holes are provided;
a first conductive member with which at least one of the first through holes is filled; and
a second conductive member with which at least one of the second through holes is filled.

7. The multilayer printed wiring board according to claim 6, further comprising:
an insulating member with which at least one of the first through holes is filled; and
a wiring pattern formed on the first insulating substrate such that the wiring pattern passes the insulating member.

8. The multilayer printed wiring board according to claim 6, wherein at least one of the first through holes is hollow.

9. The multilayer printed wiring board according to claim 6, wherein the first conductive member projects from and/or does not project from the first insulating substrate.

10. The multiplayer printed wiring board according to claim 9, wherein when the first conductive member projects from the first insulating substrate, the first conductive member has a substantially truncated conical shape with one or more projections formed on a tip of the truncated cone and/or a substantially conical shape.
